(19) United States
(12) Patent Application Publication
(10) Pub. No.: US 2025/0285965 A1
(43) Pub. Date: Sep. 11, 2025

(54) PINWHEEL-SHAPED CONNECTIONS BETWEEN DIAGONALLY OPPOSITE INTEGRATED CIRCUITS IN A MULTI-CHIP MODULE TO REDUCE NUMBER OF ROUTING LAYERS

(71) Applicant: International Business Machines Corporation, Armonk, NY (US)

(72) Inventors: David Schneider, Karlsruhe (DE); Jason Lee Frankel, Wappingers Falls, NY (US); Hubert Harrer, Schoenaich (DE)

(21) Appl. No.: 18/597,807

(22) Filed: Mar. 6, 2024

(51) Int. Cl. H01L 23/528; H01L 25/065

(52) U.S. Cl. CPC H01L 23/528; H01L 25/0655

(57) ABSTRACT

A multi-chip module with a reduced number of routing layers. The multi-chip module, such as a quad-chip module, includes identical integrated circuits arranged in a coplanar manner, where the identical integrated circuits are rotated by either 0, 90 or 180 degrees with respect to each other. Furthermore, the multi-chip module includes pinwheel-shaped connections between diagonally positioned integrated circuits. Pinwheel-shaped connections refer to arc-shaped connections in the form of a pinwheel, such as similar to the lightweight vanes that revolve at the end of the stick of the pinwheel. For example, a transmitter macro in one of the identical integrated circuits is connected to a receiver macro in a diagonally located integrated circuit in the multi-chip module using such a pinwheel-shaped connection. By utilizing such pinwheel-shaped connections, which may be routed under the dies, the crossing of the diagonal connections is eliminated and the number of wiring layers is reduced.

### TECHNICAL FIELD

The present disclosure relates generally to multi-chip modules, and more particularly to pinwheel-shaped connections between diagonally opposite integrated circuits in a multi-chip module to reduce the number of routing layers.

### BACKGROUND

Due to the performance growth for future servers, modules with more than two large logic dies per substrate are required. A module refers to the assembly of integrated circuits (“chips”) along with the package (e.g., organic laminate, ceramic module) which carries the separate integrated circuits. A die is a small block of semiconductor material on which a design/integrated circuit is fabricated. A die includes various components required for a processor's operation. These components include transistors, which serve as the building blocks of digital logic circuits, allowing for data processing and storage. An integrated circuit (“chip”) is a small electronic device made up of multiple interconnected electronic components, such as transistors, resistors, and capacitors.

For example, such modules may correspond to a quad-chip module. A quad-chip module may consist of four processors, such as four central processors, each fabricated on a die. These central processors receive instructions and perform calculations or operations to satisfy those instructions. Each central processor can perform operations separately from the other central processors. They may also work together to perform parallel operations on a shared set of data.

Furthermore, in certain situations, such central processor (CP) integrated circuits (fabricated on a die) of the module, such as the quad-chip module, need to be identical in order to reduce the number of mask sets. Masks are used to produce a pattern on a substrate. Several masks may be used in combination, where each one reproduces a layer of the completed design, and together they are known as a mask set. By utilizing identical CP integrated circuits, the use of mask sets is reduced.

Furthermore, each of the identical CP integrated circuits on the module, such as the quad-chip module, needs to be connected to each other with a low latency, high-speed bidirectional interconnect. Ideally, each CP integrated circuit should be directly connected, within a single hop, to all other CP integrated circuits on the module.

Currently, such CP integrated circuits in the module are connected to each other by directly connecting adjacent and diagonally placed CP integrated circuits. Such diagonal connections are crisscrossed essentially forming an “X.”

Standard approaches to resolve the crossing of diagonal connections is by adding more routing layers and/or using other advanced packaging technologies, such as bridges, interposers (electrical interface routing which is used to spread a connection to a wider pitch or to reroute a connection to a different connection), etc. Such approaches though add complexity and cost.

Unfortunately, there is not currently a means for connecting each of the CP integrated circuits to all other CP integrated circuits in the module, such as the quad-chip module, with low latency, high-speed bidirectional interconnects without the crossing of the diagonal connections which requires additional routing layers and/or using advanced packaging technologies.

### SUMMARY

In one embodiment of the present disclosure, a multi-chip module comprises identical integrated circuits arranged in a coplanar manner, where the identical integrated circuits are rotated by either 0 degrees, 90 degrees or 180 degrees with respect to each other. The multi-chip module further comprises pinwheel-shaped connections between diagonally positioned integrated circuits of the identical integrated circuits.

Furthermore, in one embodiment of the present disclosure, the pinwheel-shaped connections are not crossed amongst each other.

Additionally, in one embodiment of the present disclosure, the multi-chip module further comprises input/output macros asymmetrically placed along edges of the identical integrated circuits.

Furthermore, in one embodiment of the present disclosure, the input/output macros are spaced to open a wiring channel between transmitter macros and receiver macros of the input/output macros.

Additionally, in one embodiment of the present disclosure, a transmitter macro and a receiver macro of a subset of the input/output macros located along an edge of an identical integrated circuit of the identical integrated circuits are connected to a receiver macro and a transmitter macro, respectively, located along an edge of a neighboring integrated circuit of the identical integrated circuits.

Furthermore, in one embodiment of the present disclosure, a transmitter macro and a receiver macro of a subset of the input/output macros located along an edge of an identical integrated circuit of the identical integrated circuits are connected to a receiver macro and a transmitter macro, respectively, located along an edge of a diagonally located integrated circuit of the identical integrated circuits using the pinwheel-shaped connections.

Additionally, in one embodiment of the present disclosure, two input/output macros of the input/output macros located along an edge of an identical integrated circuit of the identical integrated circuits are connected to two input/output macros of the input/output macros located along an edge of a diagonally located integrated circuit of the identical integrated circuits using the pinwheel-shaped connections.

Furthermore, in one embodiment of the present disclosure, a portion of the input/output macros located along each edge of the identical integrated circuits are offset with respect to each other.

Additionally, in one embodiment of the present disclosure, transmitter macros and receiver macros of the input/output macro located along each edge of the identical integrated circuits have N rows of controlled collapse chip connection signals, where M rows of the controlled collapse chip connection signals are escaped on a same routing layer.

Furthermore, in one embodiment of the present disclosure, N/M wiring layers are used for routing the pinwheel-shaped connections.

Additionally, in one embodiment of the present disclosure, transmitter macros and receiver macros of the input/output macros located along each edge of the identical integrated circuits have 4 rows of controlled collapse chip connection signals, where 2 rows of the controlled collapse chip connection signals are escaped on a same routing layer.

Furthermore, in one embodiment of the present disclosure, 2 wiring layers are used for routing the pinwheel-shaped connections.

Additionally, in one embodiment of the present disclosure, the pinwheel-shaped connections are placed under the identical integrated circuits.

Furthermore, in one embodiment of the present disclosure, the pinwheel-shaped connections are routed under the identical integrated circuits and through wiring channels.

Additionally, in one embodiment of the present disclosure, the identical integrated circuits are shaped in a rectangular manner.

Furthermore, in one embodiment of the present disclosure, a number of the identical integrated circuits corresponds to four identical integrated circuits.

Additionally, in one embodiment of the present disclosure, the identical integrated circuits correspond to central processors.

In another embodiment of the present disclosure, a multi-chip module comprises identical integrated circuits arranged in a coplanar manner, where two identical integrated circuits of the identical integrated circuits are rotated by 0 degrees or 180 degrees with respect to two other identical integrated circuits of the identical integrated circuits. The multi-chip module further comprises input/output macros asymmetrically placed along a horizontal center axis and a vertical center axis.

Furthermore, in one embodiment of the present disclosure, the identical integrated circuits are shaped in a rectangular manner.

Additionally, in one embodiment of the present disclosure, the identical integrated circuits have an aspect ratio that is not equal to 1.

Furthermore, in one embodiment of the present disclosure, a portion of the input/output macros positioned along the vertical center axis are connected to a portion of the input/output macros positioned along the horizontal center axis using pinwheel-shaped connections.

Additionally, in one embodiment of the present disclosure, a subset of the input/output macros are located on an identical position on the identical integrated circuits with respect to a chip center axis.

Furthermore, in one embodiment of the present disclosure, the input/output macros are spaced to open a wiring channel between transmitter macros and receiver macros of the input/output macros.

Additionally, in one embodiment of the present disclosure, a number of the identical integrated circuits corresponds to four identical integrated circuits.

Furthermore, in one embodiment of the present disclosure, the four identical integrated circuits comprise a plurality of input/output macros that are unused, where the plurality of unused input/output macros are placed along an outer edge of the four identical integrated circuits.

Accordingly, embodiments of the present disclosure provide a means for connecting each of the integrated circuits to all other integrated circuits in the multi-chip module (e.g., quad-chip module) with low latency, high-speed bidirectional interconnects without the crossing of the diagonal connections. Furthermore, embodiments of the present disclosure reduce the number of wiring layers and enable the placement of the identical integrated circuits to be very close to each other.

Additionally, embodiments of the present disclosure minimize the inefficiently used area of the multi-chip module by rotating two identical integrated circuits 180 degrees with respect to two other identical integrated circuits, where each integrated circuit has an aspect ratio that is not equal to 1.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of the present disclosure of a multi-chip module;

FIG. 2 illustrates a wiring channel between transmitter macros and receiver macros in accordance with an embodiment of the present disclosure;

FIG. 3 illustrates an area of the multi-chip module that is being inefficiently used in accordance with an embodiment of the present disclosure; and

FIG. 4 illustrates an arrangement of the integrated circuits of the multi-chip module that minimizes the inefficiently used area of the multi-chip module in accordance with an embodiment of the present disclosure.

### DETAILED DESCRIPTION

In one embodiment of the present disclosure, a multi-chip module comprises identical integrated circuits arranged in a coplanar manner, where the identical integrated circuits are rotated by either 0 degrees, 90 degrees or 180 degrees with respect to each other. The multi-chip module further comprises pinwheel-shaped connections between diagonally positioned integrated circuits of the identical integrated circuits.

In this manner, each of the integrated circuits connects to all other integrated circuits in the multi-chip module (e.g., quad-chip module) with low latency, high-speed bidirectional interconnects without the crossing of the diagonal connections. Furthermore, in this manner, there is a reduction in the number of wiring layers and the identical integrated circuits are able to be placed very close to each other.

Furthermore, in one embodiment of the present disclosure, the pinwheel-shaped connections are not crossed amongst each other.

In this manner, the crossing of the diagonal connections is prevented.

Additionally, in one embodiment of the present disclosure, the multi-chip module further comprises input/output macros asymmetrically placed along edges of the identical integrated circuits.

In this manner, the identical integrated circuits can be placed close to each other. Furthermore, in this manner, the wiring may have the same symmetry as the integrated circuits thereby more easily and effectively performing the layout and electrical verification of the multi-chip module.

Furthermore, in one embodiment of the present disclosure, the input/output macros are spaced to open a wiring channel between transmitter macros and receiver macros of the input/output macros.

In this manner, the number of wiring layers is reduced.

Additionally, in one embodiment of the present disclosure, a transmitter macro and a receiver macro of a subset of the input/output macros located along an edge of an identical integrated circuit of the identical integrated circuits are connected to a receiver macro and a transmitter macro, respectively, located along an edge of a neighboring integrated circuit of the identical integrated circuits.

In this manner, the number of wiring layers is reduced.

Furthermore, in one embodiment of the present disclosure, a transmitter macro and a receiver macro of a subset of the input/output macros located along an edge of an identical integrated circuit of the identical integrated circuits are connected to a receiver macro and a transmitter macro, respectively, located along an edge of a diagonally located integrated circuit of the identical integrated circuits using the pinwheel-shaped connections.

In this manner, the crossing of the diagonal connections is prevented. Furthermore, in this manner, the number of wiring layers is reduced by utilizing pinwheel-shaped connections.

Additionally, in one embodiment of the present disclosure, two input/output macros of the input/output macros located along an edge of an identical integrated circuit of the identical integrated circuits are connected to two input/output macros of the input/output macros located along an edge of a diagonally located integrated circuit of the identical integrated circuits using the pinwheel-shaped connections.

In this manner, the crossing of the diagonal connections is prevented. Furthermore, in this manner, the number of wiring layers is reduced by utilizing pinwheel-shaped connections.

Furthermore, in one embodiment of the present disclosure, a portion of the input/output macros located along each edge of the identical integrated circuits are offset with respect to each other.

In this manner, the number of wiring layers is reduced.

Additionally, in one embodiment of the present disclosure, transmitter macros and receiver macros of the input/output macro located along each edge of the identical integrated circuits have N rows of controlled collapse chip connection signals, where M rows of the controlled collapse chip connection signals are escaped on a same routing layer.

In this manner, a multi-chip module with such a structure may be utilized to reduce the number of wiring layers.

Furthermore, in one embodiment of the present disclosure, N/M wiring layers are used for routing the pinwheel-shaped connections.

In this manner, the number of wiring layers is reduced by utilizing pinwheel-shaped connections.

Additionally, in one embodiment of the present disclosure, transmitter macros and receiver macros of the input/output macros located along each edge of the identical integrated circuits have 4 rows of controlled collapse chip connection signals, where 2 rows of the controlled collapse chip connection signals are escaped on a same routing layer.

In this manner, a multi-chip module with such a structure may be utilized to reduce the number of wiring layers.

Furthermore, in one embodiment of the present disclosure, 2 wiring layers are used for routing the pinwheel-shaped connections.

In this manner, the number of wiring layers is reduced by utilizing pinwheel-shaped connections.

Additionally, in one embodiment of the present disclosure, the pinwheel-shaped connections are placed under the identical integrated circuits.

In this manner, the crossing of the diagonal connections is prevented. Furthermore, in this manner, the number of wiring layers is reduced by utilizing pinwheel-shaped connections.

Furthermore, in one embodiment of the present disclosure, the pinwheel-shaped connections are routed under the identical integrated circuits and through wiring channels.

In this manner, the crossing of the diagonal connections is prevented. Furthermore, in this manner, the number of wiring layers is reduced by utilizing pinwheel-shaped connections.

Additionally, in one embodiment of the present disclosure, the identical integrated circuits are shaped in a rectangular manner.

In this manner, the wiring may have the same symmetry as the integrated circuits thereby enabling the layout and electrical verification of the multi-chip module to be more easily and effectively performed.

Furthermore, in one embodiment of the present disclosure, a number of the identical integrated circuits corresponds to four identical integrated circuits.

In this manner, there is a reduction in the number of wiring layers as well as the elimination of the crossing of the diagonal connections in a multi-chip module, such as a quad-chip module with four identical integrated circuits.

Additionally, in one embodiment of the present disclosure, the identical integrated circuits correspond to central processors.

In this manner, there is a reduction in the number of wiring layers as well as the elimination of the crossing of the diagonal connections in a multi-chip module, such as a multi-chip module with central processors.

In another embodiment of the present disclosure, a multi-chip module comprises identical integrated circuits arranged in a coplanar manner, where two identical integrated circuits of the identical integrated circuits are rotated by 0 degrees or 180 degrees with respect to two other identical integrated circuits of the identical integrated circuits. The multi-chip module further comprises input/output macros asymmetrically placed along a horizontal center axis and a vertical center axis.

In this manner, by implementing such an arrangement of the integrated circuits of the multi-chip module, the inefficiently used area of the multi-chip module is minimized.

Furthermore, in one embodiment of the present disclosure, the identical integrated circuits are shaped in a rectangular manner.

In this manner, by utilizing identical integrated circuits shaped in a rectangular manner, the inefficiently used area of the multi-chip module is minimized.

Additionally, in one embodiment of the present disclosure, the identical integrated circuits have an aspect ratio that is not equal to 1.

In this manner, by placing identical integrated circuits at 0 or 180 degree rotations, the inefficiently used area of the multi-chip module is minimized.

Furthermore, in one embodiment of the present disclosure, a portion of the input/output macros positioned along the vertical center axis are connected to a portion of the input/output macros positioned along the horizontal center axis using pinwheel-shaped connections.

In this manner, the inefficiently used area of the multi-chip module is minimized.

Additionally, in one embodiment of the present disclosure, wherein a subset of the input/output macros are located on an identical position on the identical integrated circuits with respect to a chip center axis.

In this manner, these macros end up exactly opposite each other in the 0/180 degree configurations and thus can be directly connected.

Furthermore, in one embodiment of the present disclosure, the input/output macros are spaced to open a wiring channel between transmitter macros and receiver macros of the input/output macros.

In this manner, the inefficiently used area of the multi-chip module is minimized.

Additionally, in one embodiment of the present disclosure, a number of the identical integrated circuits corresponds to four identical integrated circuits.

In this manner, the inefficiently used area of a multi-chip module, such as a quad-chip module, is minimized.

Furthermore, in one embodiment of the present disclosure, the four identical integrated circuits comprise a plurality of input/output macros that are unused, where the plurality of unused input/output macros are placed along an outer edge of the four identical integrated circuits.

In this manner, the inefficiently used area of a multi-chip module, such as a quad-chip module, is minimized.

As stated above, due to the performance growth for future servers, modules with more than two large logic dies per substrate are required. A module refers to the assembly of integrated circuits (“chips”) along with the package (e.g., organic laminate, ceramic module) which carries the separate integrated circuits. A die is a small block of semiconductor material on which a design/integrated circuit is fabricated. A die includes various components required for a processor's operation. These components include transistors, which serve as the building blocks of digital logic circuits, allowing for data processing and storage. An integrated circuit (“chip”) is a small electronic device made up of multiple interconnected electronic components, such as transistors, resistors, and capacitors. For example, such modules may correspond to a quad-chip module. A quad-chip module may consist of four processors, such as four central processors, each fabricated on a die. These central processors receive instructions and perform calculations or operations to satisfy those instructions. Each central processor can perform operations separately from the other central processors. They may also work together to perform parallel operations on a shared set of data. Furthermore, in certain situations, such central processor (CP) integrated circuits (fabricated on a die) of the module, such as the quad-chip module, need to be identical in order to reduce the number of mask sets. Masks are used to produce a pattern on a substrate. Several masks may be used in combination, where each one reproduces a layer of the completed design, and together they are known as a mask set. By utilizing identical CP integrated circuits, the use of mask sets is reduced. Furthermore, each of the identical CP integrated circuits on the module, such as the quad-chip module, needs to be connected to each other with a low latency, high-speed bidirectional interconnect. Ideally, each CP integrated circuit should be directly connected, within a single hop, to all other CP integrated circuits on the module. Currently, such CP integrated circuits in the module are connected to each other by directly connecting adjacent and diagonally placed CP integrated circuits. Such diagonal connections are crisscrossed essentially forming an “X.” Standard approaches to resolve the crossing of diagonal connections is by adding more routing layers and/or using other advanced packaging technologies, such as bridges, interposers (electrical interface routing which is used to spread a connection to a wider pitch or to reroute a connection to a different connection), etc. Such approaches though add complexity and cost. Unfortunately, there is not currently a means for connecting each of the CP integrated circuits to all other CP integrated circuits in the module, such as the quad-chip module, with low latency, high-speed bidirectional interconnects without the crossing of the diagonal connections which requires additional routing layers and/or using advanced packaging technologies.

The embodiments of the present disclosure provide a means for connecting each of the CP integrated circuits to all other CP integrated circuits in the module, such as the quad-chip module, with low latency, high-speed bidirectional interconnects without the crossing of the diagonal connections. In one embodiment, the identical integrated circuits (e.g., CP integrated circuits) of a multi-chip module (e.g., quad-chip module) are arranged in a coplanar manner, where the identical integrated circuits are rotated by either 0 degrees, 90 degrees or 180 degrees with respect to each other. Furthermore, I/O (input/output) macros are placed asymmetrically along the edges of the identical integrated circuits. A macro, as used herein, is a reusable piece of logic block that can be used in a design without the necessity of building them from scratch. As a result, macros can speed up the design process by allowing for the reuse of complex circuitry. These macros can include components, such as memory blocks, standard cells, pins, etc. I/O macros, as used herein, refer to macros used in the communication between the integrated circuit (e.g., CP integrated circuit) and outside its world. Such I/O macros include transmitter macros and receiver macros, which are configured to deliver and receive information, respectively. In one embodiment, such I/O macros are spaced to open a wiring channel between the transmitter macros and receiver macros. In one embodiment, a portion of the I/O macros located along an edge of an integrated circuit in the multi-chip module is connected to a portion of the I/O macros located along an edge of a diagonally located integrated circuit of the multi-chip module using pinwheel-shaped connections. Pinwheel-shaped connections, as used herein, refer to arc-shaped connections in the form of a pinwheel, such as similar to the lightweight vanes that revolve at the end of the stick of the pinwheel. For example, a transmitter macro in one of the integrated circuits of the multi-chip module is connected to a receiver macro in a diagonally located integrated circuit in the multi-chip module using such a pinwheel-shaped connection. By utilizing such pinwheel-shaped connections, which may be routed under the dies, the crossing of the diagonal connections is eliminated. Furthermore, by placing I/O macros asymmetrically along the edges of the integrated circuits as well as utilizing pinwheel-shaped connections as discussed above, the number of wiring layers is reduced (only requires layers that are needed for die area escape, which refers to the routing from signal pins to outside of the die region) as well as enabling the placement of the identical integrated circuits to be very close to each other. Furthermore, by the wiring having the same symmetry as the integrated circuits, the layout and electrical verification of the multi-chip module may be more easily and effectively performed. A further description of these and other features will be provided below.

In some embodiments of the present disclosure, the present disclosure comprises a multi-chip module with a reduced number of routing layers. In one embodiment of the present disclosure, the multi-chip module, such as a quad-chip module, includes identical integrated circuits arranged in a coplanar manner, where the identical integrated circuits are rotated by either 0 degrees, 90 degrees or 180 degrees with respect to each other. Furthermore, the multi-chip module includes pinwheel-shaped connections between diagonally positioned integrated circuits. Pinwheel-shaped connections, as used herein, refer to arc-shaped connections in the form of a pinwheel, such as similar to the lightweight vanes that revolve at the end of the stick of the pinwheel. For example, a transmitter macro in one of the identical integrated circuits is connected to a receiver macro in a diagonally located integrated circuit in the multi-chip module using such a pinwheel-shaped connection. By utilizing such pinwheel-shaped connections, which may be routed under the dies, the crossing of the diagonal connections is eliminated. Furthermore, the number of wiring layers is reduced (only requires layers that are needed for die area escape, which refers to routing from signal pins to outside of the die region) as well as enabling the placement of the identical integrated circuits to be very close to each other.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

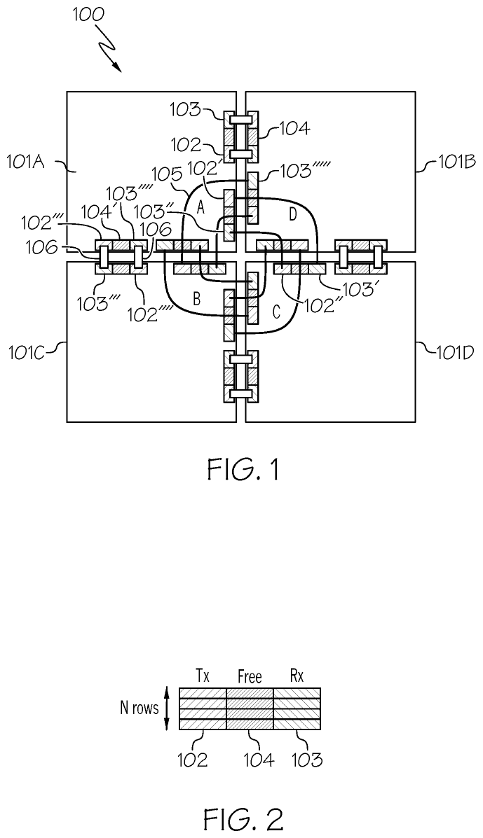

Referring now to the Figures in detail, FIG. 1 illustrates an embodiment of the present disclosure of a multi-chip module 100. The term “chip,” as used herein, refers to an integrated circuit.

As shown in FIG. 1, multi-chip module 100 corresponds to a quad-chip module, which includes four integrated circuits 101A-101D (identified as “F” in FIG. 1), such as CP integrated circuits. The letter “F” is used to show the orientation (e.g., rotated by 0, 90, 180, and 270 degrees) of integrated circuits 101A-101D, which may be identical, with respect to each other. Integrated circuits 101A-101D may collectively or individually be referred to as integrated circuits 101 or integrated circuit 101, respectively. While the following discusses such integrated circuits 101 as corresponding to central processor integrated circuits, such integrated circuits 101 may include any logic that is not necessarily limited to processor functionality, such as network, graphics, etc. functionality. A person of ordinary skill in the art would be capable of applying the principles of the present disclosure to such implementations. Furthermore, embodiments applying the principles of the present disclosure to such implementations would fall within the scope of the present disclosure.

In one embodiment, integrated circuits 101 are identical, such as in the embodiment in which multi-chip module 100 corresponds to a quad-chip module in which there is a need to reduce the number of mask sets. In one embodiment, integrated circuits 101 are shaped in a rectangular manner as shown in FIG. 1. Examples of integrated circuit 101 include, but are not limited to, a graphics processor, system on a chip, etc.

In one embodiment, integrated circuits 101 are arranged in a coplanar manner, where integrated circuits 101 are rotated by either 0 degrees, 90 degrees or 180 degrees with respect to each other. For example, as illustrated in FIG. 1, integrated circuits 101 are rotated by 90 degrees with respect to each other.

Furthermore, as shown in FIG. 1, multi-chip module 100 includes I/O (input/output) macros 102, 103 that are placed asymmetrically along the edges of integrated circuits 101. A macro, as used herein, is a reusable piece of logic block that can be used in a design without the necessity of building them from scratch. As a result, macros can speed up the design process by allowing for the reuse of complex circuitry. These macros can include components, such as memory blocks, standard cells, pins, etc. I/O macros, as used herein, refer to macros used in the communication between the integrated circuit (e.g., CP integrated circuit) and outside its world. Such I/O macros include transmitter macros 102 and receiver macros 103, which are configured to deliver and receive information, respectively.

In one embodiment, such I/O macros 102, 103 are spaced to open a wiring channel 104 between transmitter macros 102 and receiver macros 103 as illustrated in FIG. 2. Wiring channel 104, as used herein, refers to the area of the I/O macro that does not have signal pins which belong to the high-speed interconnect and would block routing of the connections.

Referring to FIG. 2, FIG. 2 illustrates a wiring channel (e.g., wiring channel 104) between transmitter macros (e.g., transmitter macros 102) and receiver macros (e.g., receiver macros 103) in accordance with an embodiment of the present disclosure.

As shown in FIG. 2, there are N rows of pins in transmitter macro 102 and receiver macro 103 as well as wiring channel 104 between transmitter macro 102 and receiver macro 103. As a result, a wiring channel, such as wiring channel 104, is located opposite a transmitter or receiver portion of the macro on a neighboring integrated circuit 101.

Returning to FIG. 1, in conjunction with FIG. 2, in one embodiment, a portion of I/O macros 102, 103 located along an edge of integrated circuit 101 are connected to a portion of I/O macros 103, 102, respectively, located along an edge of a diagonally located integrated circuit 101 using pinwheel-shaped connections 105. Pinwheel-shaped connections, as used herein, refer to arc-shaped connections in the form of a pinwheel, such as similar to the lightweight vanes that revolve at the end of the stick of the pinwheel. These connections can be sets of an arbitrary number of single-ended and/or differential signal traces escaped on any number of layers. For example, transmitter macro 102′ in integrated circuit 101A is connected to receiver macro 103′ in a diagonally located integrated circuit 101D in multi-chip module 100 using such a pinwheel-shaped connection 105. In another example, transmitter macro 102″ in integrated circuit 101D is connected to receiver macro 103″ in a diagonally located integrated circuit 101A in multi-chip module 100 using such a pinwheel-shaped connection 105.

In one embodiment, such pinwheel-shaped connections 105 are routed under integrated circuits 101. In one embodiment, such pinwheel-shaped connections 105 are routed under integrated circuits 101 and through wiring channels.

Referring again to FIG. 1, FIG. 1 illustrates that pinwheel-shaped connections 105 are not crossed amongst each other. By utilizing such pinwheel-shaped connections 105, the crossing of the diagonal connections in prior approaches is eliminated.

Furthermore, as shown in FIG. 1, a portion of I/O macros 102, 103 located along an edge of integrated circuit 101 are directly connected to a portion of I/O macros 103, 102, respectively, located along an edge of a neighboring (adjacent) integrated circuit 101. For example, transmitter macro 102′″ located along an edge in integrated circuit 101A is connected to receiver macro 103″″ located along an edge in the neighboring (adjacent) integrated circuit 101C in multi-chip module 100 using connection 106. In another example, transmitter macro 102″″″ located along an edge in integrated circuit 101C is connected to receiver macro 103″″″ located along an edge in the neighboring (adjacent) integrated circuit 101A in multi-chip module 100 using connection 106. Additionally, as illustrated in FIG. 1, a wiring channel 104, such as wiring channel 104′, is located between such transmitter macros 102 and receiver macros 103 (e.g., transmitter macros 102″″″, 102″″″″ and receiver macros 103″″, 103″″″).

In one embodiment, two I/O macros, such as a pair of transmitter and receiver macros 102, 103 (e.g., transmitter macro 102″ and receiver macro 103′ of integrated circuit 101D), located along each edge of integrated circuits 101 are connected to a pair of receiver and transmitter macros 103, 102, respectively, (e.g., receiver macro 103″ and transmitter macro 102′ of integrated circuit 101A) located along an edge of a diagonally located integrated circuit (e.g., integrated circuit 101A) using pinwheel-shaped connections 105.

Furthermore, as illustrated in FIG. 1, a portion of input/output macros 102, 103 located along each edge of integrated circuits 101 are offset with respect to input/output macros 103, 102, respectively, located along each edge of neighboring (adjacent) integrated circuits 101, where such input/output macros 102, 103 are connected to input/output macros 103, 102, respectively, in diagonally located integrated circuits 101 using pinwheel-shaped connections 105. For example, transmitter macro 102′ of integrated circuit 101A is located offset with respect to receiver macro 103″″″″ located in integrated circuit 101B, where transmitter macro 102′ and receiver macro 103″″″″ are connected to receiver and transmitter macros 103, 102, respectively, located in diagonally located integrated circuits 101 using pinwheel-shaped connections 105.

In one embodiment, the placement of the power vias is optimized, such as placing power vias off-grid (off the manufacturing grid, placement grid or routing grid) or centering power vias under controlled collapse chip connections. A via, as used herein, is a hole that goes through two or more layers. A power via, as used herein, refers to a via used to allow power to travel between layers. By optimizing the placement of the power vias, vertical power delivery stays intact with under-die routing of pinwheel-shaped connections 105.

By placing I/O macros 102, 103 asymmetrically along the edges of integrated circuits 101 as well as utilizing pinwheel-shaped connections 105 as discussed above, the number of wiring layers is reduced (only requires layers that are needed for die area escape, which refers to the routing from signal pins to outside of the die region) as well as enabling the placement of the identical integrated circuits 101 to be very close to each other.

For example, if multi-chip module 100 corresponds to a quad-chip module, which includes four CP integrated circuits (e.g., integrated circuits 101), transmitter and receiver macros 102, 103 have N rows of controlled collapse chip connection signals. Furthermore, in such an embodiment, there are M rows of controlled collapse chip connection signals that can be escaped on the same routing layer. “Escaped,” as used herein, refers to routing signals, such as controlled collapse chip connection signals, under the die thereby routing such signals through an appropriate number of layers. Without the use of the present disclosure, 2*N/M wiring layers are used for routing diagonal interconnections. However, using the architecture of multi-chip module 100 as discussed herein, only N/M wiring layers are used for routing diagonal interconnections (pinwheel-shaped connections 105). As a result, there is a significant reduction in stack-up complexity and cost.

For instance, referred to the above example, if transmitter and receiver macros 102, 103 have 4 rows of controlled collapse chip connection signals and there are 2 rows of controlled collapse chip connection signals that can be escaped on the same routing layer, then without the use of the present disclosure, 4 wiring layers are used for routing diagonal interconnections. However, using the architecture of multi-chip module 100 as discussed herein, only 2 wiring layers are used for routing diagonal interconnections (pinwheel-shaped connections 105). As a result, there is a significant reduction in stack-up complexity and cost.

Furthermore, by the wiring having the same symmetry as integrated circuits 101, the layout and electrical verification of the multi-chip module (e.g., multi-chip module 100) may be more easily and effectively performed.

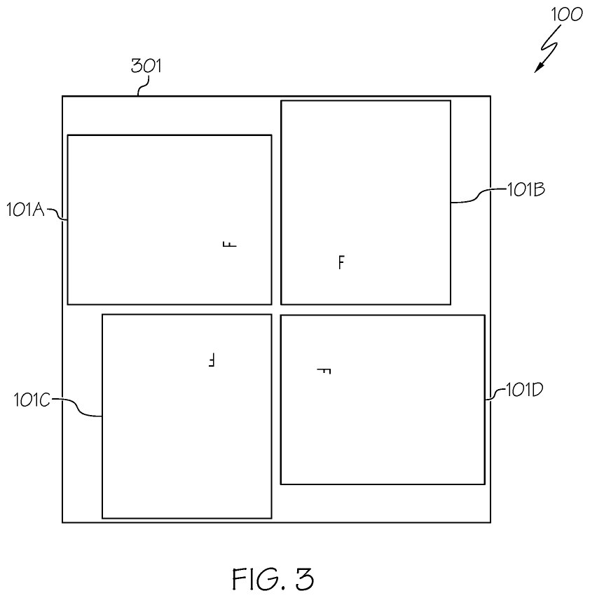

Additionally, when the aspect ratio of the identical integrated circuits (e.g., integrated circuits 101A-101D) is not equal to 1, and the identical integrated circuits (e.g., integrated circuits 101A-101D) are placed at rotations other than 0 or 180 degrees with respect to each other, the area of multi-chip module 100 may be inefficiently used as discussed below in connection with FIG. 3. Aspect ratio, as used herein, refers to the height and width ratio of integrated circuits 101.

In situations in which the chip aspect ratio is not equal to 1, and integrated circuits (chips) have rotations which differ by 90 degrees, an undesirably large (bounding box area/total chip area) ratio may result as illustrated in FIG. 3.

FIG. 3 illustrates an area of multi-chip module 100 that is being inefficiently used in accordance with an embodiment of the present disclosure.

Referring to FIG. 3, in conjunction with FIG. 1, laminate area 301 refers to the bounding box area of integrated circuits 101A-101D on multi-chip module 100. Laminate area 301 has extents equal to the bounding box of the array of integrated circuits 101A-101D, which is the smallest rectangle which fully contains all of integrated circuits 101A-101D. As shown in FIG. 3, the bounding box area exceeds the total chip area, referring to the area on multi-chip module 100 that is being used to place integrated circuits 101A-101D. In such an example, by suboptimally using the area of multi-chip module 100, an undesirably large (laminate area/total chip area) ratio may result.

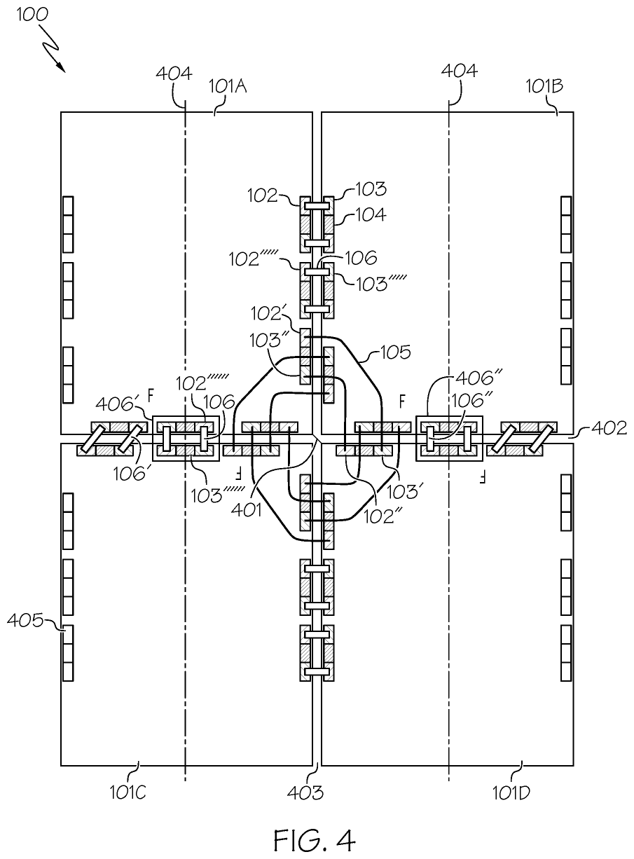

The principles of the present disclosure optimally use the area of multi-chip module 100 for integrated circuits 101 that have an aspect ratio that is not equal to 1 as discussed below in connection with FIG. 4. Aspect ratio, as used herein, refers to the height and width ratio of integrated circuits 101. Furthermore, the principles of the present disclosure optimally use the area of multi-chip module 100 by arranging two integrated circuits 101 to be rotated 0 or 180 degrees with respect to two other integrated circuits 101 as discussed below in connection with FIG. 4.

FIG. 4 illustrates an arrangement of the integrated circuits (e.g., integrated circuits 101) of the multi-chip module (e.g., multi-chip module 100, such as a quad-chip module) that minimizes the inefficiently used area of the multi-chip module in accordance with an embodiment of the present disclosure.

Referring to FIG. 4, in conjunction with FIG. 1, multi-chip module 100 includes two integrated circuits 101 (e.g., integrated circuits 101A, 101B) that are rotated 180 degrees with respect to two other integrated circuits 101 (e.g., integrated circuits 101C, 101D). In one embodiment, integrated circuits 101 are identical, such as in the embodiment in which multi-chip module 100 corresponds to a quad-chip module in which there is a need to reduce the number of mask sets. In one embodiment, integrated circuits 101 are shaped in a rectangular manner as shown in FIG. 4.

Furthermore, as illustrated in FIG. 4, integrated circuits 101 have an aspect ratio that is not equal to 1 (i.e., the height of integrated circuit 101 does not equal the width of integrated circuit 101).

By rotating two integrated circuits 101 (e.g., integrated circuits 101A, 101B) 180 degrees with respect to two other integrated circuits 101 (e.g., integrated circuits 101C, 101D), where such integrated circuits 101 have an aspect ratio that is not equal to 1, a minimum amount of inefficiently used area is possible. In such an embodiment, input/output macros 102, 103 are asymmetrically placed along the horizontal center axis 402 and the vertical center axis 403 with respect to center point 401. In one embodiment, such I/O macros 102, 103 are spaced to open a wiring channel 104 as discussed above.

In one embodiment, I/O macros 406′, 406″ (include I/O macros 102, 103) are located on an identical position on the four instances of integrated circuits 101 with respect to the chip center axes 404. As a result, such I/O macros end up exactly opposite each other in the 0 or 180 degree configurations and thus can be directly connected.

Furthermore, in one embodiment, a portion of I/O macros 102, 103 that are located along vertical center axis 403 are connected to a portion of I/O macros 103, 102, respectively, that are located along horizontal center axis 402 using pinwheel-shaped connections 105. For example, transmitter macro 102′ located along vertical center axis 403 in integrated circuit 101A is connected to receiver macro 103′ located along horizontal center axis 402 in diagonally located integrated circuit 101D in multi-chip module 100 using such a pinwheel-shaped connection 105. In another example, transmitter macro 102″ located along horizontal center axis 402 in integrated circuit 101D is connected to receiver macro 103″ located along vertical center axis 403 in a diagonally located integrated circuit 101A in multi-chip module 100 using such a pinwheel-shaped connection 105. In this manner, nearest-neighbor connections are enabled.

In one embodiment, as shown in FIG. 4, integrated circuits 101 (e.g., integrated circuits 101A-101D) within multi-chip module 100 (e.g., quad-chip module) are aligned along the chip center axes 404.

In one embodiment, such pinwheel-shaped connections 105 are routed under integrated circuits 101. In one embodiment, such pinwheel-shaped connections 105 are routed under integrated circuits 101 and through wiring channels.

Furthermore, in one embodiment, as shown in FIG. 4, a portion of I/O macros 102, 103 that are aligned along vertical center axis 403 are directly connected to I/O macros 103, 102, respectively, located along an edge of a neighboring (adjacent) integrated circuit 101. For example, transmitter macro 102″″″″ in integrated circuit 101A is connected to receiver macro 103″″″″ located in a neighboring (adjacent) integrated circuit 101B in multi-chip module 100 using connection 106. Additionally, as illustrated in FIG. 4, a wiring channel 104 is located between transmitter and receiver macros 102, 103. In this manner, nearest-neighbor connections are enabled.

Additionally, in one embodiment, as shown in FIG. 4, the portion of I/O macros 102, 103 that are connected to other I/O macros 103, 102, respectively, in the same integrated circuit 101 are aligned along horizontal center axis 402. In such an embodiment, a portion of I/O macros 102, 103 that are aligned along horizontal center axis 402 are directly connected to I/O macros 103, 102, respectively, located along horizontal center axis 402 in a neighboring (adjacent) integrated circuit 101 via connection 106. For example, transmitter macro 102″ in integrated circuit 101A is connected to receiver macro 103″″″″″ located on the other side of horizontal center axis 402 in integrated circuit 101C via connection 106.

In one embodiment, such connections 106 may be slanted, such as connection 106′, or straight, such as connection 106″, as are most of the connections 106 depicted in FIG. 4.

Furthermore, as illustrated in FIG. 4, wiring channel 104 is located between transmitter and receiver macros 102, 103, including being located along the chip center axis 404 in certain situations.

Additionally, as shown in FIG. 4, multi-chip module 100 may include input/output macros 405 that are unused in identical integrated circuits 101 (e.g., integrated circuits 101A-101D), where the unused input/output macros 405 may be placed along an outer edge of these integrated circuits 101 (e.g., integrated circuits 101A-101D).

As a result of the foregoing, by utilizing pinwheel-shaped connections, which may be routed under the dies, the crossing of the diagonal connections is eliminated. Furthermore, by placing I/O macros asymmetrically along the edges of the integrated circuits as well as utilizing pinwheel-shaped connections as discussed above, the number of wiring layers is reduced as well as enabling the placement of the identical integrated circuits to be very close to each other. Furthermore, by the wiring having the same symmetry as the integrated circuits, the layout and electrical verification of the multi-chip module may be more easily and effectively performed.

Additionally, as a result of the foregoing, the inefficiently used area of the multi-chip module is minimized by rotating two identical integrated circuits 0 or 180 degrees with respect to two other identical integrated circuits 101, where each integrated circuit 101 has an aspect ratio that is not equal to 1.

Furthermore, the principles of the present disclosure improve the technology or technical field involving multi-chip modules.

As discussed above, due to the performance growth for future servers, modules with more than two large logic dies per substrate are required. A module refers to the assembly of integrated circuits (“chips”) along with the package (e.g., organic laminate, ceramic module) which carries the separate integrated circuits. A die is a small block of semiconductor material on which a design/integrated circuit is fabricated. A die includes various components required for a processor's operation. These components include transistors, which serve as the building blocks of digital logic circuits, allowing for data processing and storage. An integrated circuit (“chip”) is a small electronic device made up of multiple interconnected electronic components, such as transistors, resistors, and capacitors. For example, such modules may correspond to a quad-chip module. A quad-chip module may consist of four processors, such as four central processors, each fabricated on a die. These central processors receive instructions and perform calculations or operations to satisfy those instructions. Each central processor can perform operations separately from the other central processors. They may also work together to perform parallel operations on a shared set of data. Furthermore, in certain situations, such central processor (CP) integrated circuits (fabricated on a die) of the module, such as the quad-chip module, need to be identical in order to reduce the number of mask sets. Masks are used to produce a pattern on a substrate. Several masks may be used in combination, where each one reproduces a layer of the completed design, and together they are known as a mask set. By utilizing identical CP integrated circuits, the use of mask sets is reduced. Furthermore, each of the identical CP integrated circuits on the module, such as the quad-chip module, needs to be connected to each other with a low latency, high-speed bidirectional interconnect. Ideally, each CP integrated circuit should be directly connected, within a single hop, to all other CP integrated circuits on the module. Currently, such CP integrated circuits in the module are connected to each other by directly connecting adjacent and diagonally placed CP integrated circuits. Such diagonal connections are crisscrossed essentially forming an “X.” Standard approaches to resolve the crossing of diagonal connections is by adding more routing layers and/or using other advanced packaging technologies, such as bridges, interposers (electrical interface routing which is used to spread a connection to a wider pitch or to reroute a connection to a different connection), etc. Such approaches though add complexity and cost. Unfortunately, there is not currently a means for connecting each of the CP integrated circuits to all other CP integrated circuits in the module, such as the quad-chip module, with low latency, high-speed bidirectional interconnects without the crossing of the diagonal connections which requires additional routing layers and/or using advanced packaging technologies.

Embodiments of the present disclosure improve such technology by the multi-chip module, such as a quad-chip module, including identical integrated circuits arranged in a coplanar manner, where the identical integrated circuits are rotated by either 0 degrees, 90 degrees or 180 degrees with respect to each other. Furthermore, the multi-chip module includes pinwheel-shaped connections between diagonally positioned integrated circuits. Pinwheel-shaped connections, as used herein, refer to arc-shaped connections in the form of a pinwheel, such as similar to the lightweight vanes that revolve at the end of the stick of the pinwheel. For example, a transmitter macro in one of the identical integrated circuits is connected to a receiver macro in a diagonally located integrated circuit in the multi-chip module using such a pinwheel-shaped connection. By utilizing such pinwheel-shaped connections, which may be routed under the dies, the crossing of the diagonal connections is eliminated. Furthermore, the number of wiring layers is reduced (only requires layers that are needed for die area escape, which refers to routing from signal pins to outside of the die region) as well as enabling the placement of the identical integrated circuits to be very close to each other. Furthermore, in this manner, there is an improvement in the technical field involving multi-chip modules.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A multi-chip module, comprising:
identical integrated circuits arranged in a coplanar manner, wherein said identical integrated circuits are rotated by either 0 degrees, 90 degrees or 180 degrees with respect to each other; and
pinwheel-shaped connections between diagonally positioned integrated circuits of said identical integrated circuits.

2. The multi-chip module as recited in claim 1, wherein said pinwheel-shaped connections are not crossed amongst each other.

3. The multi-chip module as recited in claim 1 further comprising:
input/output macros asymmetrically placed along edges of said identical integrated circuits.

4. The multi-chip module as recited in claim 3, wherein said input/output macros are spaced to open a wiring channel between transmitter macros and receiver macros of said input/output macros.

5. The multi-chip module as recited in claim 3, wherein a transmitter macro and a receiver macro of a subset of said input/output macros located along an edge of an identical integrated circuit of said identical integrated circuits are connected to a receiver macro and a transmitter macro, respectively, located along an edge of a neighboring integrated circuit of said identical integrated circuits.

6. The multi-chip module as recited in claim 3, wherein a transmitter macro and a receiver macro of a subset of said input/output macros located along an edge of an identical integrated circuit of said identical integrated circuits are connected to a receiver macro and a transmitter macro, respectively, located along an edge of a diagonally located integrated circuit of said identical integrated circuits using said pinwheel-shaped connections.

7. The multi-chip module as recited in claim 3, wherein two input/output macros of said input/output macros located along an edge of an identical integrated circuit of said identical integrated circuits are connected to two input/output macros of said input/output macros located along an edge of a diagonally located integrated circuit of said identical integrated circuits using said pinwheel-shaped connections.

8. The multi-chip module as recited in claim 3, wherein a portion of said input/output macros located along each edge of said identical integrated circuits are offset with respect to each other.

9. The multi-chip module as recited in claim 3, wherein transmitter macros and receiver macros of said input/output macro located along each edge of said identical integrated circuits have N rows of controlled collapse chip connection signals, wherein M rows of said controlled collapse chip connection signals are escaped on a same routing layer.

10. The multi-chip module as recited in claim 9, wherein N/M wiring layers are used for routing said pinwheel-shaped connections.

11. The multi-chip module as recited in claim 3, wherein transmitter macros and receiver macros of said input/output macros located along each edge of said identical integrated circuits have 4 rows of controlled collapse chip connection signals, wherein 2 rows of said controlled collapse chip connection signals are escaped on a same routing layer.

12. The multi-chip module as recited in claim 11, wherein 2 wiring layers are used for routing said pinwheel-shaped connections.

13. The multi-chip module as recited in claim 1, wherein said pinwheel-shaped connections are placed under said identical integrated circuits.

14. The multi-chip module as recited in claim 1, wherein said pinwheel-shaped connections are routed under said identical integrated circuits and through wiring channels.

15. The multi-chip module as recited in claim 1, wherein said identical integrated circuits are shaped in a rectangular manner.

16. The multi-chip module as recited in claim 1, wherein a number of said identical integrated circuits corresponds to four identical integrated circuits.

17. The multi-chip module as recited in claim 1, wherein said identical integrated circuits correspond to central processors.

18. A multi-chip module, comprising:
identical integrated circuits arranged in a coplanar manner, wherein two identical integrated circuits of said identical integrated circuits are rotated by 0 degrees or 180 degrees with respect to two other identical integrated circuits of said identical integrated circuits; and
input/output macros asymmetrically placed along a horizontal center axis and a vertical center axis.

19. The multi-chip module as recited in claim 18, wherein said identical integrated circuits are shaped in a rectangular manner.

20. The multi-chip module as recited in claim 18, wherein said identical integrated circuits have an aspect ratio that is not equal to 1.

21. The multi-chip module as recited in claim 18, wherein a portion of said input/output macros positioned along said vertical center axis are connected to a portion of said input/output macros positioned along said horizontal center axis using pinwheel-shaped connections.

22. The multi-chip module as recited in claim 18, wherein a subset of said input/output macros are located on an identical position on said identical integrated circuits with respect to a chip center axis.

23. The multi-chip module as recited in claim 18, wherein said input/output macros are spaced to open a wiring channel between transmitter macros and receiver macros of said input/output macros.

24. The multi-chip module as recited in claim 18, wherein a number of said identical integrated circuits corresponds to four identical integrated circuits.

25. The multi-chip module as recited in claim 24, wherein said four identical integrated circuits comprise a plurality of input/output macros that are unused, wherein said plurality of unused input/output macros are placed along an outer edge of said four identical integrated circuits.
